(19) United States
(12) Patent Application Publication
(10) Pub. No.: US 2006/0278613 A1
(43) Pub. Date: Dec. 14, 2006

(54) Method and device for removing material from a three-dimensional surface in a multi-layered manner by means of a laser, using a polygon network which is described by a mathematical function and represents the surface

(76) Inventor: Raul Hess, Hovath (DE)

Correspondence Address: HENRY M FEIEREISEN, LLC, 350 FIFTH AVENUE, SUITE 4714, NEW YORK, NY, 10118, US

(21) Appl. No.: 10/572,756

(22) PCT Filed: Sep. 24, 2004
(86) PCT No.: PCT/EP04/10715

§ 371 Date: Mar. 20, 2006

(51) Int. Cl. B44C 1/22; H01L 21/306

(52) U.S. Cl. 216/83; 216/94; 156/345.24

(57) ABSTRACT

The invention relates to a method for removing material from a three-dimensional surface (1) of any shape in a single or multilayered manner by means of a material removing agent (9), such as a laser, that acts in points on the a surface and where a surface structure (2) is applied to the three-dimensional surface (1); wherein the inventive methods can be carried out in such a way that the surface (1) is described by a mathematical function and approximated by a polygon whereby each polygon of the polygon network is assigned to a work area for the laser. Raster images are associated with each of the polygons, which determine the depth values for the surface structure. The polygons (3) are removed line by line. When the depth values of the surface structure differ by a large margin, the material removal takes place in several layers (7) of polygon networks.

The invention refers to a method and device for removal of material in accordance with a set of instructions, for example, a so-called master model. The material removal is carried out on a three-dimensional surface of any configuration, especially one that is not planar or of a rotation-symmetric shape and wherein the depth of removal of the material may differ at each point on the surface.

Methods for producing a surface structure on a surface of any configuration of a three-dimensional surface require time consuming and expensive production steps in order to realize precision in the micrometer range. Up to now, such a surface structure was produced by etching methods in the form of layer by layer removal of material from a surface, or a galvanic method, whereby the positive mold with the desired surface structure is covered with a metal, which becomes the negative tool for producing the desired form part or foil. These various methods always require a great number of process steps in order to produce a negative mold for only a single surface structure. As a result, for each change in the surface structure, the same process steps have to be repeated.

Up to now, two methods are common when providing a grain to a mold in an economically efficient way; in one instance it is the etching grain, wherein the surface of the body of any topology is partially masked and then material is selectively removed by the etching fluid. This method works in a limited way also for a layer by layer removal, however in that case it produces a steplike transition between the grain peaks and the grain valleys. Additionally, difficulties in graining are encountered when trying to grain complex surface geometries.

Another method is the so-called galvano process, where, a positive model, the so-called model to be leather-grained is covered with a foil (or leather), which has the desired grain. In a molding process, the (leather)-grain is transferred to a negative mold, which in turn is utilized to produce a (positive) bath-model. Then, in the galvanic bath, a metal layer is galvanically deposited. Subsequnetly, the so-obtained galvano mold must be reinforced, and it can only be utilized as is for the production of certain parts if the surface of the galvano mold is not subject to much stress. The slush process and the spray skin process are particularly common; however, these latter two are work intensive and costly. As an alternative, lasers offer themselves for the removal of material. The technology for the removal of material by means of laser is known from DE 393 9866 for laser engraving. Of major importance is a true and detailed copy of the object with an essentially two-dimensional, that is, a flat surface. Thus, the material removal follows at an essentially constant depth. However, copying of a three-dimensional surface structure is not the subject of such methods, and thus the problem of material removal for the production of a three-dimensional structure is not an issue there.

The material removal through evaporation of a surface layer by means of laser is known from DE 4209933 C2, where the laser beam is expanded and guided by pivoting deflection mirrors via a computer generated reference line. The reference lines form a raster array. The laser follows the lines of the raster array in several loops along reference lines that are offset from one another at an angle whereby the material is removed through evaporation. The systematic appearance of raised portions in the boundary layer is eliminated by varying the direction of the laser tracks by a certain angle through rotation in the machining plane. Thus, a network like structure of raster lines is created. This technology is likewise applied exclusively on two-dimensional surfaces having a constant depth. With the technology as disclosed in the DE 4209933 C2, a uniform removal of material in the raster array can be realized.

As disclosed in DE 10032981 A1, a laser is guided line by line in the paths (raster lines), respectively tracks, in each of the areas to be machined by the laser. The tracks are made on a moving body of any topology. In order to prevent, that sharp separation lines form in the overlapping region of the tracks at the border areas, such as would be, for example, formed through excessive material removal in the overlap region, the border areas are offset from one another at each removal run. In other words, during line by line removal in a particular region, the laser does not stop at the line but stops only near the line. While the terminal point of the material removal is thus in proximate distance to the line, the distance range differs from line to line. This leads to a statistical distribution of the terminal points about the mean value of the line so that no optical defect can be seen. This method is only suitable for removal from raster arrays that are all located on one plane. As soon as the raster arrays are inclined relative to one another, a different amount of material is removed, when the removal agent is moving away from the field. In such a case, it would mean that each single terminal point determining removal of material would have to be recorded and the removal of material anticipated for the adjacent grid would have to be corrected. For the foregoing reasons, applying this method to three-dimensional surfaces could work thus only with a great amount of additional computing time.

The layer by layer removal of material for the production of three-dimensional structures is disclosed in U.S. Pat. No. 6,300,595 B1 and U.S. Pat. No. 6,407,361 B1, where lines on a three-dimensional computer generated graphics are converted into tracks. These tracks are located on flat layers. The material is removed along those tracks on each of these flat layers. The length of the tracks is derived by computation from the three-dimensional graphics. Advantageously, the graphics consist of simple modeled objects such as semi-circles or pyramids. While the possibility to assemble several such simple geometric graphics into a complex art piece is discussed, it is evident that material removal for each of these graphics would have to be done sequentially. This would cause problems with the machining steps in each layer with respect to the transitions in the machining fields, thereby causing either ridges or holes in the pattern. This problem does not occur when using graphics for making a rotation symmetrical pattern in a planar surface, but for the foregoing reasons do not render the methods disclosed in the two patents suitable for complex surface structures.

According to the teaching of DE 10116672 A1, coarse and fine structures are machined in different ways such that fine areas are machined by means of laser and coarse areas by means of a stripping device. This technology is suitable in particular for machining metal surfaces, for example printing drums. Machining the coarse areas is performed by mechanical removal devices.

It is known for example, that by removing material by laser, complex structures can be produced as for example in the micromachining of materials. There are also methods for the removal of material from large surfaces by laser. However, up to now, the known laser methods were not successfully used on any curved surfaces for applying a texture in which the aacuracy of the removal must be in the μm range. According to the afore-discussed prior art, this is due to the fact that the polygons of the polygon network are not located in one plane. However, the machining area of the removal agent is located in one plane, which means the depth of the removal varies as soon as the removal agent leaves that plane.

It is an object of the invention, to produce a surface structure, such as for example a grain, on bodies of an arbitrary topology by removing material from three-dimensional surfaces of any shape. This surface can be at least approximately described by a mathematical function, also called the master model and covered with a polygon network. Each point in the polygon network is associated with a value for the depth measurement of the surface structure. This value can be expressed as a series of gray levels which are associated with one or more pixels on the master texture bitmap. Alternatively, this value can also be expressed in colors or color intensities; in an abstract way, they can also be numerical values that are proportional to the depth of the material removal. It follows that gray levels are used as a representational example for this assignment of values. Thus, each gray level forms at least one master texture bitmap, whereby the master texture bitmap is associated with a polygon of the polygon network of the master model. The sum of the master texture bitmaps results in the surface of the master model. Each of the polygons of the master model can be selected in a size so that its master texture bitmap corresponds to the area to be machined. An area to be machined is determined by the machining procedure of the removal agent. If the removal agent is a laser, the machining area is located within its focal cuboid. A focal cuboid forms when laser beams, using a flat array condensing lens at a pre-determined position of the scanner, are directed to the surface of a body of any topology so that a point precise removal of material can be realized. The distance between scanner and the central plane of the focal cuboid is given through the focal distance of the laser optics. The height of the machining area, at a predetermined maximum failure of the thickness of the removed layer, is given through the maximum depth of focus (=deviation from the depth of focus); and its lateral length through the corresponding maximum deflection of the galvanic mirrors located in the scanner. Within the focal cuboid, the machining area can be approximated by a polygon, whose corners are all located on one surface, which ideally has the exact distance of the focal distance to the laser optics and extends vertical to the direction of the laser beam in the central position of the deflection mirror.

The polygon in the machining area contains a gray level bitmap, obtained through parallel projection of the master texture bitmap onto the polygon of the machining area. In turn, the sum of the polygons of the machining areas results in the surface. The gray level bitmap contains all information about the surface structure to be realized through removal of material. The surface structure of each partial surface is thus converted into a raster image, as described in the example of the afore-discussed gray level bitmap consisting of pixels, such that each of the sections of the surface to be machined comes to be located entirely within the focal area of the laser. The position of the pixels on the polygon in the three dimensional space corresponds to a two-dimensional coordinate position on the surface of the raster images, that is, the gray level bitmap.

The polygon networks of each section plane are arranged in an offset manner so that the edges of polygons of the same kind are never superposed. Thereby, the angle orientation as well as the size of the polygons can vary from layer to layer.

The material removal in the machining area is carried out by the removal agent in such a way that material is removed from the same spot until the value of the gray level is reached. For this purpose, the removal agent covers the machining area and removes material at the spots where the gray levels are not yet reached and proceeds further to the next machining area until all the areas have been machined by the removal agent and thus finalized the material removal in the first layer. For the next following layer, the removal follows in the same manner. Material is only removed in spots where the gray level value has not yet been attained; in the remaining spots no material removal takes place.

The possibility is thus given to provide the surface of a body of any type configuration with the most natural appearing three-dimensional structure. An example of such a surface structure is the grain of leather, which is characterized by grain peaks of varying heights and expansions and wherein the transition between the grain peaks and the grain valleys is uniform. This surface structure can be mapped using gray levels arranged on the section plane for transferring into a machine readable form. This information can then be processed by a computer data processing program into control information for a removal device. A laser device is especially suitable as removal agent since the desired precision in the μm range can be realized.

A further object of the invention is to prevent visible separating-or border lines due to material removal where the separating lines are formed as ridges or grooves in the border sections of the machining area.

A further object is to realize optional variants of surface structures simply by programming the removal agent. The desired surface can be the result of either a simulation, a manipulation of the master model by means of a graphics program, or a 3d scan translated directly into the computer control for the line by line removal from the surface and producing the surface structure.

These objects are realized through the following method for the single-or multilayer material removal from a variously shaped three-dimensional body by means of a removal agent, such as a laser, acting on the surface in order to produce a surface structure on the three-dimensional surface, where the surface structure can be described by a mathematical function and thus approximated through a polygonal network. As follows, the surface structure should also be designated as surface texture. The method for producing a texture on a surface of an arbitrarily curved configuration, where the surface can be defined by a mathematical function, includes the division of the surface into a plurality of partial surfaces. The partial surfaces describe a portion of the texture through a number of pixels, associated with a gray level. Each partial surface thus illustrates a distribution of gray levels. Each gray level is associated with a distance value, which represents the shortest distance of the tangent plane in a pixel corresponding to a point on the surface texture. The material removal can be done in several layers, wherein each layer is assigned its own polygon network. The number of layers in which the removal is to take place is determined by the distance value. This distance value can be a multiple of the layer thickness. The layers can be described by the same mathematical function as the curved surface. Each layer is composed of partial surfaces that are polygons with the pixel indicating when the distance value is greater than the sum of the thickness of the layers, which are located between the curved surface and the respective layer. In an advantageous embodiment, no partial surface in the respective layer to be machined shares a border region with the partial surface previously worked on. The partial surfaces of adjacent layers thus do not share a common edge. Edges of partial surfaces of a neighboring layer should not be superposed, since material removal in the border section of the layer is prone to failure. A failure can result in the formation of a ridge or can result in a hole. The partial surfaces of neighboring layers are arranged in an either offset manner, or are rotated relative to one another, or are randomly arranged. Additionally, or as an alternative, the partial surfaces of adjacent layers can have different sizes. Each layer is associated with its own polygon network. The partial surface to be machined in each layer has no border region in common with one of the previously machined partial surfaces. In a further advantageous embodiment, for each partial surface, respectively each polygon, a different angle orientation for the laser tracks is set. Since the laser strikes the partial surface obliquely, further failures at the border area are thereby prevented.

The polygon network is read into the control program of a removal agent for determining the areas to be machined. Such a machining area includes at least one partial surface. The machining area is within the focal area of a removal agent, which runs through the machining area line by line. The removal agent is switched on when a pixel is located in the layer of the partial surface. The removal agent is switched off when no pixel is recognized in the layer, which is the case when the gray level value associated with the pixel indicates that no further removal should take place. If this value is a brightness value and the maximum removal is coupled to the darkest value (black), then the removal is terminated when reaching the brightness value of the pixel. The brighter the pixel the fewer layers are being removed. If the maximum removal is however coupled to the brightest value, then material is being removed in correspondingly more layers, the brighter the corresponding pixel is. Instead of brightness values, color intensity, spectral ranges, wave lengths or comparable graduators can be used, in so far as these are suitable to be graphically represented on a surface structure of a model or, can be transformed through graphic representation in this model by means of a set of definite instructions for the multi-layered material removal.

This method can be applied to all materials suitable for removal by the selected removal agent. As compared to each of the known etching methods or galvanic methods, this method offers the possibility to produce within a short time a grained surface of high quality with few limitations relative to the configuration of the surface structure and with respect to the selection of the material, it is only important that the material is suitable for the material removal in the desired precision range.

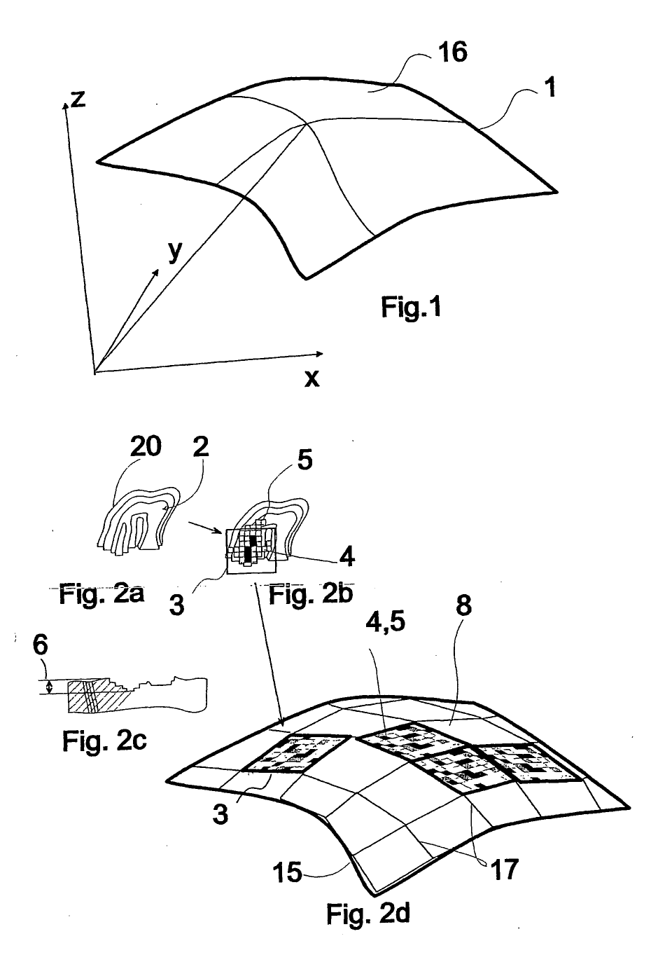

FIG. 1 is an illustration of a curved surface.

FIG. 2a is an illustration of a texture as a layered image.

FIG. 2b is the illustration of the translation of the texture into a raster image.

FIG. 2C is a section through a texture.

FIG. 2D is the illustration of the partial surfaces with the raster images.

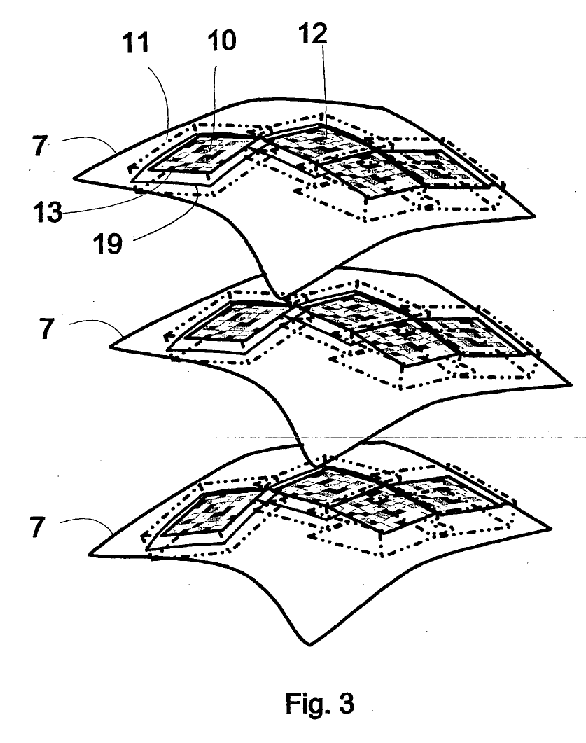

FIG. 3 is an illustration of the layers with the partial surface and the raster images.

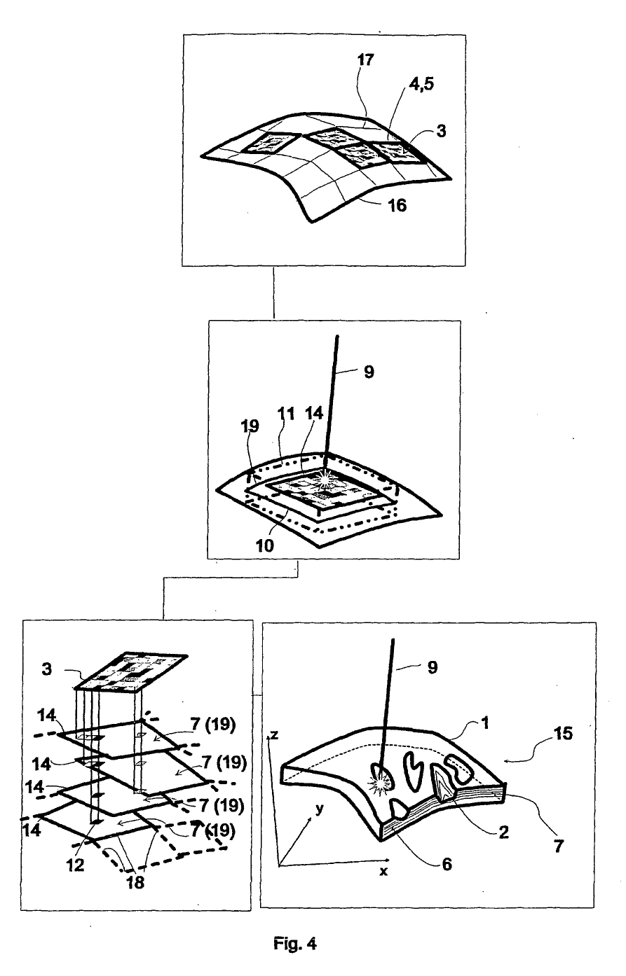

FIG. 4 is a schematic illustration of the method.

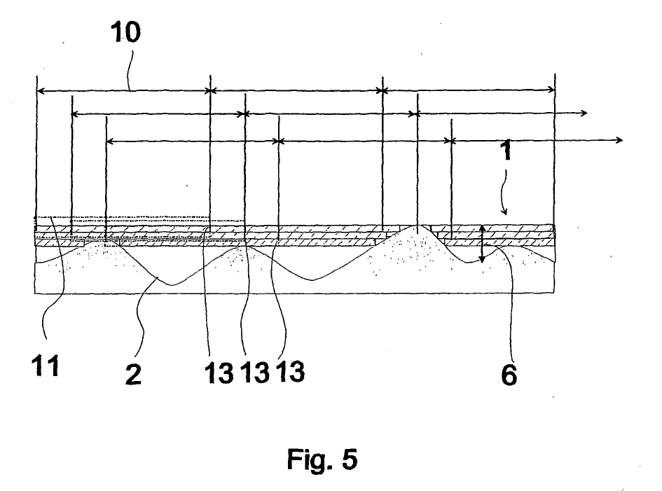

FIG. 5 is an illustration of removal of a surface in several layers.

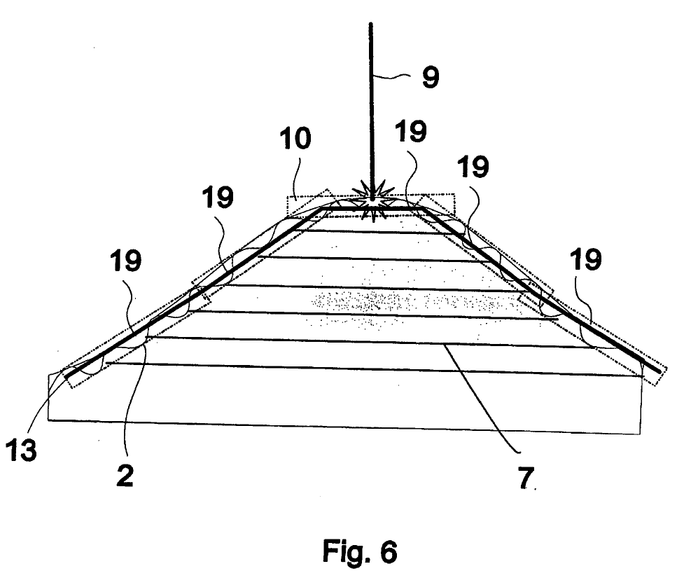

FIG. 6 is the illustration of the removal of curved surfaces.

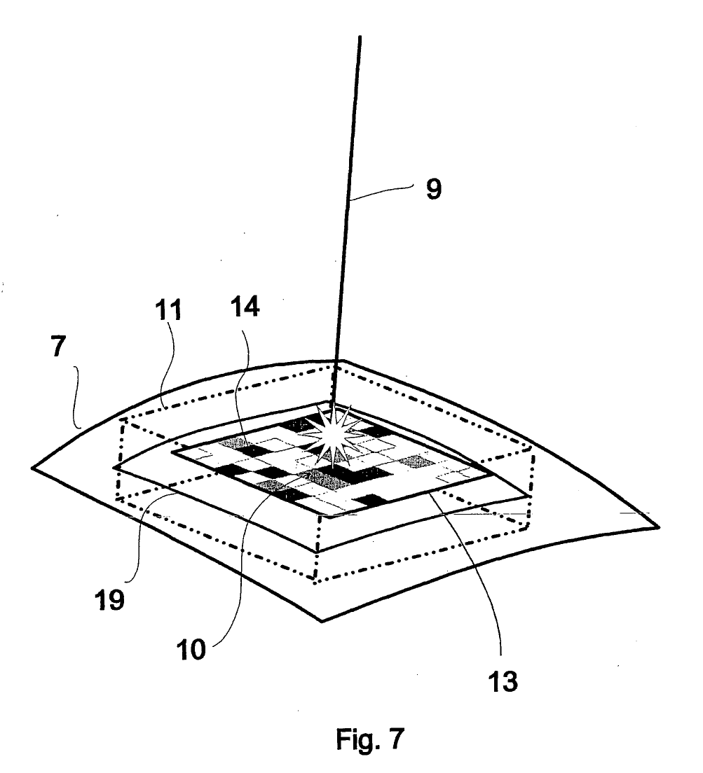

FIG. 7 is a detail of FIG. 6 in three-dimensional illustration.

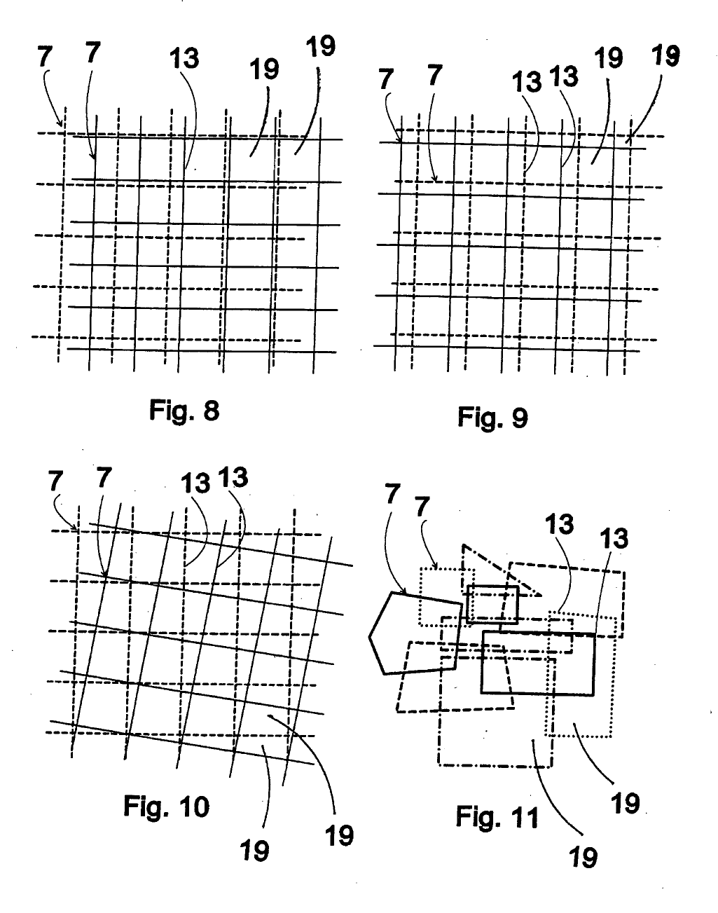

FIG. 8 shows a first arrangement of two adjacent layers.

FIG. 9 shows a second arrangement of two adjacent layers.

FIG. 10 shows a third arrangement of two adjacent layers.

FIG. 11 shows a fourth arrangement of two adjacent layers.

FIG. 1 is an illustration of a curved surface 1, which can be described by a mathematical function. This curved surface 1 should be provided with a texture 2, that is, a surface structure. With the present invention, a method for the layer by layer selective removal of material from a body of any topology 15, that is, also a body with the afore-discussed surface 1 is realized. Thus, a surface structure 2 can be produced on a body of any topology 15 in the form of, for example, a grain; in particular, such a surface structure 2 should possibly have uniform transitions between grain peaks and grain valleys. Furthermore, with respect to the topology of the surface structure 2, there should be no restrictions as to, for example, cylindrical or flat surfaces. Such surface structures or grains must be able to be represented in such a way that they can be produced by known methods for the removal of material, especially a laser method.

FIG. 2a shows such a surface structure 2 in a two-dimensional illustration. The depth of the texture is schematically represented and corresponds to the peak lines in a map. The contour 20 of the surface structure 2 is arbitrarily selected, just as peak lines are. This contour 20 is to be created by means of the removal agent 9. The removal agent 9 can be a laser. Material removal is realized by evaporating the material through heat generated by the laser. The computer controlled laser beam is guided along the machining area 10 across the body of any topology 15 in accordance with the removal specifications as set forth in the following paragraphs. For large surfaces, the work is carried out in sections, so that the entire material removal is finished in a single section before another section is started.

FIG. 2b illustrates how the texture 2 is translated into a raster image. There is a difference between the description of the topology, that Is, the geometry of a chosen topology of a body 15 and the grain, that is, the desired fine structure of the surface, which is produced through a form-giving method on the body of any topology—or more general—of a curved surface. This screen image or master texture bitmap 3 is composed of pixels 4, wherein the gray level 5 represents a measure for the distance value 6 of the non-machined curved surface to the base level or floor of the surface texture 2. In other words, the method for the production of a texture 2 on any curved surface 1 comprises the removal of material in layers 7, where the surface is represented by a mathematical function. This surface is divided into partial surfaces, the polygons of a polygon network 17, as illustrated in the example in FIG. 2d. The partial surfaces, that is, the polygons of the polygon network, are associated with a screen image, the master texture bitmap. The master texture bitmap 3 describes a portion of texture 2 through a series of pixels 4, to which a gray level 5 is assigned. Each surface portion shows thus a distribution of gray levels 5 via a number of pixels 4, whereby each gray level 5 is assigned a distance value 6, corresponding the normal distance of the tangential plane at the curved surface 1 in this pixel to the grain surface. This distance value 6 is schematically depicted for the distance from the curved surface 1 to the deepest point of the grain 2.

In the automotive industry, NURBS (non-uniform rational B-splines) are generally utilized to describe the topology of so-called free-form surfaces, that is, curved surfaces that are expressed by mathematical functions. If a complex geometric shape cannot be satisfactorily expressed by a single NURBS-surface, several such NURBS patches are assembled next to each other. Oftentimes they are cut or trimmed prior to assembly, whereby NURBS curves which are located on the NURBS surface are utilized.

In order to start machining the topology with removal agent 9, such as for example a laser, the surface has to be divided into work areas 10. The work areas 10 are shown in more detail in FIG. 3. The size of the work area 10 is ideally selected so that the removal agent 9 can cover the section line by line. If the removal agent 9 is a laser, with a respective position of the scanner (possibly approximating vertical to the work section 10), scanning is carried out by simply adjusting the galvanic mirrors. Furthermore, the change of distance between scanner and the surface portion 19 should be kept small. In any case, selecting the size of work area 10 should be so as to prevent any undesired change of the amount of material removal which could be the result of changing the position of the angle of the removal agent, such as a laser, or changing the distance between the partial surface 19 and the scanner. Care must be taken that each work section 10 comes entirely within the focal cuboid 11 of the removal agent 9.

Using a flat field lens, a work area to be machined, at a certain position of the scanner, can be described through the focal cuboid. The distance between scanner und the central plane of the focal cuboid is given by the focal depth of the laser optics. The height of the work area at a given maximum error for the thickness of the removed layer is determined by the maximum focal distance (=deviation from the focal length), while the lateral length is given by the corresponding maximum deflection of the galvanic mirrors in the scanner.

Within the focal cuboid 11, the work area 10 is approximated by a polygon, whose corners are located at a surface which ideally is exactly the distance of the focal distance to the laser optics and oriented perpendicular to the direction of the laser beam in the central position of the deflection mirrors. This polygon corresponds now to the partial surface 19 of the layer 7 to be machined, wherein the work area 10 is created by projection of the polygon onto the NURBS surface and must be completely within the focal cuboid 11.

The entire topology of the surface 1 to be worked on is thus described by a raster field of connected partial surfaces 19 or polygons of different sizes and shapes. The border regions 13, that is, the polygon edges, are to be selected independently from the borders of the partial surface 19 describing the NURBS patches to be worked on, that is, it can and will occur, that one or more spots of the polygon are located on one patch and one or more spots of the polygon on the adjacent NURBS patch.

For the description of a fine structure of the surface, each polygon is assigned a raster image 14 (bitmap) for improved processing by the control program of the laser. This raster image 14 corresponds essentially to the partial surface 19 and is assembled of pixels of various levels of gray 12. FIG. 7 illustrates, that the screen image 14 does not exactly correspond to the partial surface 19. Here, the size of the pixel approximates the size of the cross section of the laser light cone, while the gray level 12 (brightness) of the pixel corresponds to the depth of the surface structure 2 at this point. A white spot means for example, that no material was removed, as compared to a black spot which indicates a maximum removal of material (or vice versa).

An even greater precision can be realized through description of the laser point by several raster images in the bitmap, where the differential material removal can be computed backwards across the diameter of the laser point. The resulting disadvantage is an enlargement of the bit map and the attendant higher storage requirement and the higher computing efforts in the electronic controls.

The encoding of the bitmap corresponds thereby to the maximum number of layers 7, that is, at 256 gray levels (=8 bit) per image point, maximally, 256 layers can be represented. Storing this raster image requires various known computer formats with corresponding compressing algorithms that can result in a large reduction of storage requirement.

In general, a partial surface, that is, the polygon, will rarely be square shaped. Therefore, the corner points of the polygon in the three-dimensional space are assigned each to a corresponding point in the bitmap 14 in 2D-coordinates (texture coordinates).

FIG. 4 illustrates the connection between the raster image which contains the pixels 4 with their gray levels 5 and the layers 7, which follow essentially the shape of the curved surfaces. Thus, the layers 7, like the surface, can be described essentially with the identical mathematical functions or with a series of mathematical functions which are represented as NURBS-patches. The different gray levels 5 are projected onto the single layers as an instruction for the removal of material. The layer itself can be divided into partial surfaces 19, which should be conceived so that the precision of the material removal through removal agent 9 is realized. The gray level 12 corresponds to a maximum depth of the removal. Accordingly, when scanning each layer with removal agent 9, removal will be carried out at the spot corresponding to gray level 12. The sum of the removals per layer thus constitutes the entire material removal.

The sequence of the method is illustrated in FIG. 4 in a schematic way as follows. The method for the multilayered removal of material from a body of any topology 15 having an arbitrarily shaped three-dimensional surface 1 is effected by means of a removal agent, such as a laser, acting on a surface in a point by point manner, and by means of which a surface structure 2 is realized on the three-dimensional surface 1. On the surface 1, sections to be worked on 10 are defined, whereby such a section 10 is determined through the focal area 11 of the removal agent. The surface 1 is approximated by superposed polygon networks 18, whereby each of the polygons 19 of the polygon network 18 is assigned to the work section 10 of the removal agent 9.

The surface structure 2 is described by at least one gray level bitmap 14. The gray level bitmap 14 comprises pixels of varying gray levels 12 or various color scales. The depth of the material removal is determined by brightness of the gray level 12 corresponding to each gray level bitmap 14 or the intensity of the color scale, or the parameter of the color, such as for example a wavelength, when using multicolored bit maps.

The material removal is done in a number of layers 7, which correspond to the gray level 12. Each layer 7 is assigned its own polygon network 18. The respective polygon 19 to be machined in each layer 7 does not share a border section with the polygon previously machined, thereby preventing the occurrence of negative visual effects at the edges which would indicate the stop and go action of the removal agent on the surface.

When performing the process, an original three-dimensional computer model 16 of a body of any chosen topology 15 is generated and described by an original polygon network 17. The three-dimensional corners of the polygons of the original polygon network 17 correspond to two-dimensional spots in one or more master texture bitmaps 3. The polygons are transferred into the two-dimensional space of the master texture bitmap 3, whereby the gray level 5 of a pixel 4 of the master texture bitmap 3 corresponds to the requisite material removal at the body of chosen topology 15 and the areas to be machined 10 comprise single layers 7. The total sum of the areas to be machined result in surface 1 and the total sum of the layers 7 results in the surface structure 2 of the body of any chosen topology 15. Any layer is described by the polygon network 18 and the superposed polygon networks are arranged offset relative to one another. The surface structure 2of the body of any chosen topology 15 is approximately described by superposed networks 18, which are arranged in an offset manner. Within the work area 10, each polygon 19 of the polygon network 18 is assigned to a gray level bitmap from the parallel projection of the master texture bitmap 3 of the polygon 19 within the area to be machined 10, so that the material removal by the removal agent 9 can be realized in each layer 7 in accordance with the value of the gray level bitmap 14. The distance value 6 between the layers 7 corresponds thus to the difference in brightness between two adjacent gray levels 12.

The master model is derived from the description of the body of chosen topology by CAD-(spline)-surfaces which combine into the original polygon network 17.

The brightness value of the gray levels 12 of the gray level bitmap 14 are computed backwards relative to the master texture bitmap, prior to or during the machining of the surface 1 of the body of any topology 15. Instead of brightness values of the gray levels 12, color scales or colors from the color spectrum can also be utilized.

FIG. 5 shows an illustration of how the process of removal functions in an essentially flat portion of the texture 2. The removal follows from the surface 1 in layers that are essentially of a constant thickness. Satisfactory results for an exact reproduction of the texture were obtained at a layer thickness of 5 μm. The laser utilized for the removal Nd: YAG can remove a layer of at least 5 μm. Advantageously, the raster images 4 are sized 4 times the thickness of the layer, since there are always blurred areas in the border sections. The border sections not only comprise the edges of the polygons 19 but also the border sections 13 of the gray level 12 up to where there is maximal removal in that layer. Also shown in FIG. 5, is the layer by layer removal and that the removal is carried out until the desired contour of the surface structure 2 is realized. The shown distance value 6 from the surface 1 to the contour is precisely the gray level 12 up to which removal is taking pace. Also shown is that each layer 7 with respect to the adjacent layers is divided into machining areas 10 which are arranged relative to each other in an offset manner. The areas to be worked on comprise the partial surfaces 19. The offset arrangement is discussed further below.

With the respective arrangement of the polygons 19, it is also possible to combine the texture coordinates of several polygons in one bitmap. Besides, when computing and storing the polygons and corresponding bitmaps, the orientation of the laser angle should be considered. The laser tracks need not necessarily follow the raster lines of the bitmap, but computer graphics methods exist which compute the brightness values for the raster lines running obliquely to the laser track using anti-aliasing-algorithms. (compare: a line extending diagonal across a computer screen).

When working on any type topology of a body, a removal agent must be used, for example, here a laser device, where the scanner, containing the galvano mirrors, has a certain maneuverability relative to the body of that topology in order to reach the most vertical position relative to each polygon with distance to the focal distance of the laser optics, that is, corresponding to that position which served as a basis for computing the polygons.

Controlling the laser device in an efficient way requires organizing the polygons in the database such that they are read by the electronic control in sequence resulting in the least amount of flawed line reading by the scanner. FIG. 6 illustrates a section through a curved surface 1, wherein the partial surfaces 19 are arranged essentially parallel to the curved surface 1. For simplicity's sake, only a single layer 7 is shown with its partial surfaces 19. The removal agent carries out a removal action along the partial surface 19, wherein the removal is realized only in the area not within the contour of the surface structure 2. The area to be machined 10 can thereby coincide with the border areas 13 of the partial surface 19. Such a machining area 10 can however also be combined from several partial surfaces 19 or polygons.

FIG. 7 shows again in detail how the removal from the partial surface 19 is done. The removal agent 9 scans the raster image which is assigned to the partial surface 19, and carries out a material removal at each location where the gray level 12 is larger or the same (smaller or the same) value for the gray level of layer 7 to which the partial surface 19 belongs. The raster image 14 in this case is smaller than the partial surface 19, resulting in an overlap of the adjacent work areas 10 with the focal area 1 1. This arrangement can be advantageous, when the curvature of the surface which is formed by the partial surface 19 is suitably large so that a change in the layer removal realized in dependence of the characteristics of the removal agent, would thus lead to an uneven material removal showing up as a flaw in the surface structure to be produced.

Examples of how to prevent separating lines, which originate in the area where the laser track ends and the next one starts, are shown in FIGS. 8-11. These separating lines are generated by either increased or decreased removal of material at the edges of the polygon. They are generated when edges of areas to be machined, respectively polygons, in one layer border each other.

The thickness of the layer can be reduced to an extent that the border line thereby created has a height which is negligibly small relative to the entire height of the grain which was generated through removal of several layers and thus no longer visible. Thus, a compounding of the separating line-error at the polygon edges 13 is prevented and each layer 7 to be removed is assigned its own independent three-dimensional polygon network as illustrated in FIG. 4. Under the afore-stated rules, this can be freely selected. It must be taken into account however that the polygon borders 13 may be overlapping (it cannot be avoided), but they must not be superposed. Otherwise the separating line-error in the various layers will be compounded. This means that when observing a certain point on the surface to be machined of a body of any type topology and with a material removal in n layers that this point “belongs” to n different polygons 19 of n different polygon networks 18. Different possibilities of arrangements of adjacent layers are illustrated in FIGS. 8-11, whereby the partial surfaces 19 are polygons. The partial surfaces 19 of a layer 7 border each other through shared border sections 13. The border sections 13 of the partial surfaces 19 of adjacent layers 7 however are not superposed. According to FIG. 8, the partial surfaces 19 of adjacent layers 7 are of different size.

According to FIG. 9, the partial surfaces 19 of adjacent layers 7 are arranged in offset manner.

According to FIG. 10, the partial surfaces 19 of adjacent layers 7 are rotated relative to each other. According to FIG. 11, the partial surfaces 19 of adjacent layers 7 are arranged at random. In that case, no polygon network is used and in order to prevent visible border lines, only the rule against any superposing of single polygon edges is followed.

These polygons can either share a texture bitmap, or they distribute themselves in one to maximally n bitmaps.

With respect to the corresponding texture bitmap, it is important that when several bitmaps are present, the respective removal of layers is distributed to each of the bitmaps. This means that the final material removal at a given point results from the addition of the single gray level of the texture bitmap at this point. The above-described FIG. 4 illustrates this in detail.

If the separating line flaw needs to be further reduced, a method can be applied wherein an overlap area is formed between the areas to be machined and in which the machining laser tracks in the respective section cuts merge and the transition points are statistically distributed.

1-24. (canceled)

25. A process for producing a surface texture on an arbitrarily curved body through layer by layer removal of material comprising the steps of:
describing the surface of the arbitrarily curved body by means of at least one polygon network,
said polygon network being divided into partial surfaces of single polygons wherein each polygon corresponds to a raster image containing a plurality of pixels such that a certain number of pixels describe a detail of the surface texture of the body,
associating each pixel in the raster image a gray level to thereby provide each area with a distribution of gray levels through the number of pixels, wherein each gray level is associated a distance value corresponding to the distance of the curved surface in this pixel to the surface texture,
removing layers of material from the surface of the curved body pursuant to the gray level value by means of a removal agent.

26. The process according to claim 25, wherein the distance value determines a number of layers from which the material is removed.

27. The process according to claim 26, wherein the distance value is a multiple of a thickness of a layer.

28. The process according to claim 26, wherein a layer is described by its own polygon network.

29. The process according to claim 26, wherein a layer is constructed from partial surfaces.

30. The process according to claim 29, wherein the partial surfaces are polygons.

31. The process according to claim 29, wherein the partial surfaces of a layer adjoin one another through common border areas.

32. The process according to claim 31, wherein the border areas of the partial surfaces of adjacent layers are not superposed.

33. The process according to claim 32, wherein the partial surfaces of adjacent layers are offset relative to one another.

34. The process according to claim 32, wherein the partial surfaces of adjacent layers are rotated relative to one another.

35. The process according to claim 32, wherein the partial surfaces of adjacent layers are arranged at random.

36. The process according to claim 32, wherein the partial surfaces of adjacent layers are of different size.

37. The process according to claim 25, further comprising the step of inputting information for the polygon network constructed from partial surfaces into a computer control program for controlling the removal agent.

38. The process according to claim 37, wherein the control program determines work areas for the removal agent.

39. The process according to claim 38, wherein a work area comprises at least one partial surface.

40. The process according to claim 38, wherein a work area is located inside a focal area of the removal agent.

41. The process according to claim 38, wherein a work area is scanned line by line by the removal agent.

42. The process according to claim 41, wherein during scanning the removal agent is switched on, when a pixel with a gray level is detected in a layer of the work area.

43. The process according to claim 41, wherein during scanning the removal agent is not switched on if no pixel with a gray level is detected in a layer.

44. The process according to claim 25, wherein for a partial surface a different angle is preset for the removal agent acting on the partial surface.

45. The process according to claim 44, wherein the removal agent strikes the partial surface obliquely.

46. Apparatus for layer-by-layer removal of material from a body of random topology for producing a three-dimensional structure on the body comprising:
a computer for modeling the topology in response to a first polygon network containing information commensurate with the topology;
a removal tool operated by the computer for point-wise removal of material in dependence on the information; and
projection means for projecting the information of the first polygon network to a second polygon network having a plurality of polygons, each polygon having a work area which is associated to the removal tool and described by at least one raster image so that the removal tool executes a material removal in the work area in response to information stored in the raster image for each polygon of the second polygon network.

47. The device according to claim 46, wherein the raster image is generated by a scanning device containing information about the point-wise removal of material.

48. The device according to claim 46, wherein the removal agent has a focal area and the work area is located entirely within the focal area.
